(19) United States
(12) Patent Application Publication
(10) Pub. No.: US 2005/0136335 A1
(43) Pub. Date: Jun. 23, 2005

(54) Patterned microelectronic mask layer formation method employing multiple feed-forward linewidth measurement

(75) Inventors: Ryan Chia-Jen Chen, Chiayi (TW); Fang-Cheng Chen, Hsin-chu (TW); Li-Shiun Chen, Hsin chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/738,240

(22) Filed: Dec. 17, 2003

(51) Int. Cl. G03F 9/00; G03C 5/00

(52) U.S. Cl. 430/5; 430/322; 430/323

(57) ABSTRACT

A method for forming a patterned mask layer within a microelectronic product employs a sequential linewidth measurement and trimming of a patterned mask layer to form multiply trimmed patterned mask layer. The sequential linewidth measurement and trimming employs at least two linewidth measurements and two patterned mask layer trimmings to provide a multiply trimmed patterned mask layer having an actual linewidth intended to be near a pre-determined target linewidth.

### BACKGROUND OF THE INVENTION

1. Field of the Invention

The invention relates generally to patterned mask layers employed within microelectronic products. More particularly, the invention relates to methods for precisely forming patterned mask layers employed within microelectronic products.

2. Description of the Related Art

Microelectronic products are formed from substrates having formed thereover microelectronic devices that are connected and interconnected with patterned conductor layers. In turn, the microelectronic devices and patterned conductor layers are typically formed employing photolithographic methods.

As microelectronic device and patterned conductor layer dimensions have decreased, it has become increasingly difficult to form microelectronic devices and patterned conductor layers with precise linewidth dimensions. Precise linewidth dimensions are often critical to effecting desirable microelectronic device and microelectronic product performance. It is thus desirable to provide microelectronic products having formed therein microelectronic devices and patterned conductor layers with precise linewidth control.

Mask layer trimming methods and linewidth measurement feed forward methods are generally known in the microelectronic product fabrication art for forming microelectronic devices and patterned conductor layers with enhanced linewidth control. However, such conventional methods do not necessarily provide an optimal level of linewidth precision.

It is thus desirable to provide microelectronic products having formed therein microelectronic devices and patterned conductor layers with precise linewidth control. The present invention is directed towards the foregoing object.

### SUMMARY OF THE INVENTION

A first object of the invention is to provide a method for forming a patterned microelectronic layer.

A second object of the invention is to provide a method in accord with the first object of the invention, wherein the patterned microelectronic layer is formed with precise linewidth control.

In accord with the objects of the invention, the invention provides a method for forming a patterned mask layer employed within a microelectronic product.

The method employs a multiple sequential linewidth measurement and trimming of a patterned mask layer to form a multiply trimmed patterned mask layer that may be employed as an etch mask for forming a patterned target layer from a blanket target layer within a microelectronic product. The multiple sequential measurement and trimming of the patterned mask layer to form the multiply trimmed patterned mask layer employs at least two measurement steps and at least two trimming steps such as to provide the multiply trimmed patterned mask layer with a measured linewidth closely approximating a target linewidth. The multiply trimmed patterned mask layer may then be employed as an etch mask layer for forming a patterned target layer with precise linewidth control from a blanket target layer.

The invention provides a method for forming a patterned microelectronic layer with precise linewidth control.

The invention realizes the foregoing object within the context of a multiple sequential measurement and trimming of a patterned mask layer to form a trimmed patterned mask layer. By employing within the multiple sequential measurement and trimming at least two measurement steps and at least two trimming steps, a trimmed patterned mask layer may be formed with precise linewidth control, and thus a patterned target layer formed employing the trimmed patterned mask layer as an etch mask may also be formed with precise linewidth control.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4, FIG. 5, FIG. 6, FIG. 7 and FIG. 8 show a series of schematic cross-sectional diagrams illustrating the results of progressive stages of fabricating a patterned target layer within a microelectronic product in accord with a preferred embodiment of the invention.

### DESCRIPTION OF THE PREFERRED EMBODIMENT

The invention provides a method for forming a patterned microelectronic layer with precise linewidth control.

The invention realizes the foregoing object within the context of a multiple sequential linewidth measurement and trimming of a patterned mask layer to form a trimmed patterned mask layer. By employing within the multiple sequential measurement and trimming at least two measurement steps and at least two trimming steps, a trimmed patterned mask layer may be formed with precise linewidth control, and thus a patterned target layer formed employing the trimmed patterned mask layer as an etch mask may also be formed with precise linewidth control.

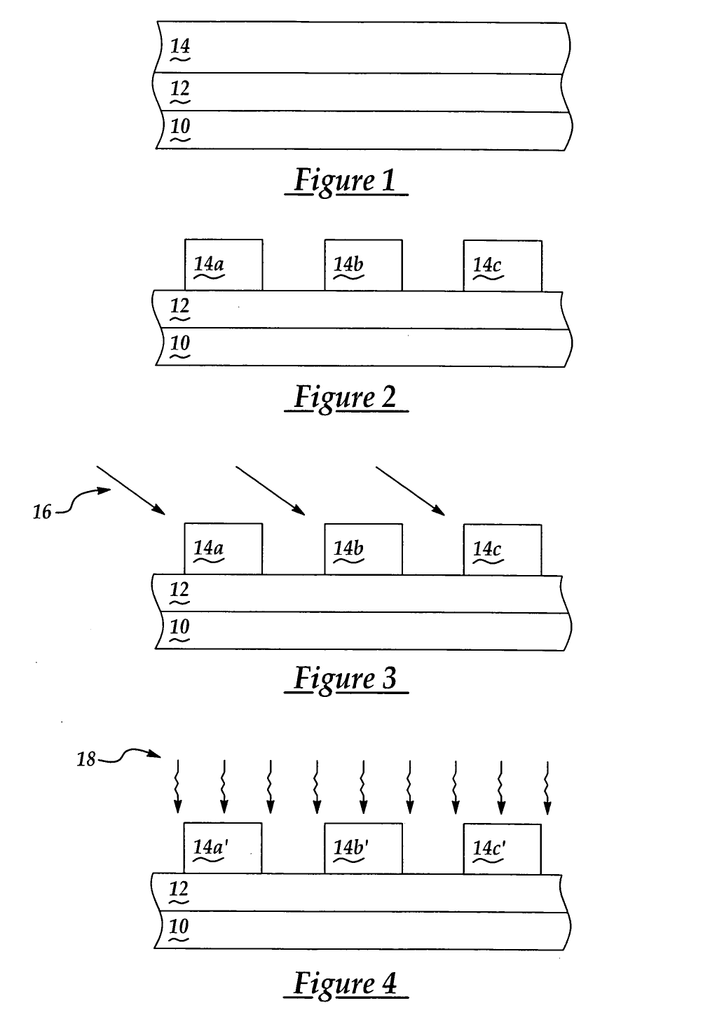

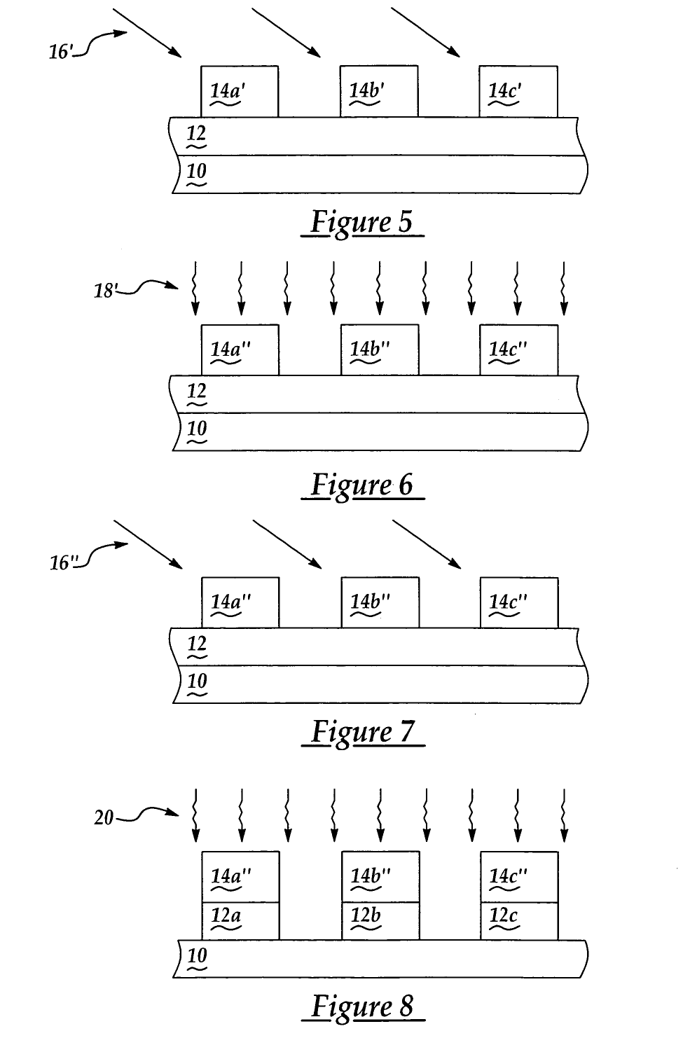

FIG. 1 to FIG. 8 show a series of schematic cross-sectional diagrams illustrating the results of progressive stages of forming a patterned target layer within a microelectronic product in accord with a preferred embodiment of the invention.

FIG. 1 shows a substrate 10 having formed thereupon a blanket target layer 12 in turn having formed thereupon a blanket mask layer 14.

Within the invention, the substrate 10 may be employed within a microelectronic product selected from the group including but not limited to semiconductor products, ceramic substrate products and optoelectronic products. In addition, the blanket target layer 12 may be formed of microelectronic materials selected from the group including but not limited to conductor materials, semiconductor materials and dielectric materials. Typically, the blanket target layer 12 is formed to a thickness of from about 200 to about 15000 angstroms. Finally, the blanket mask layer 14 may be formed of mask materials including but not limited to photoresist mask materials and hard mask materials (such as but not limited to silicon oxide, silicon nitride and silicon oxynitride hard mask materials). The photoresist mask materials are typically formed to a thickness of from about 1000 to about 20000 angstroms and the hard mask materials are typically formed to a thickness of from about 200 to about 2000 angstroms.

Preferably: (1) the substrate 10 is a semiconductor substrate having formed thereupon a gate dielectric layer formed to a thickness of from about 8 to about 100 angstroms; (2) the blanket target layer 12 is a blanket gate electrode material layer formed to a thickness of from about 1000 to about 3500 angstroms; and (3) the blanket mask layer 14 is a blanket hard mask layer formed to a thickness of from about 500 to about 2000 angstroms. The blanket gate electrode material layer may be formed of gate electrode materials including but not limited to metal, metal alloy, doped polysilicon (having a dopant concentration of from about 1E18 to about 1E22 dopant atoms per cubic centimeter) and polycide (doped polysilicon/metal silicide stack) gate electrode materials. The blanket hard mask layer may be formed of a silicon oxide, silicon nitride or silicon oxynitride hard mask material.

FIG. 2 shows the results of patterning the blanket mask layer 14 to form a series of patterned mask layers 14a, 14b and 14c. The blanket mask layer 14 may be patterned while employing methods as are conventional in the microelectronic product fabrication art. When the blanket mask layer 14 is formed of a photoresist material, the series of patterned mask layers 14a, 14b and 14c is formed employing a direct photolithographic and development method. When the series of patterned mask layers 14a, 14b and 14c is formed of a hard mask material, the series of patterned mask layers 14a, 14b and 14c is formed employing an additional blanket photoresist layer that is photoexcposed and developed to form a photomask employed for forming the series of patterned mask layers 14a, 14b and 14c. The series of patterned mask layers 14a, 14b and 14c is formed of an actual first linewidth greater than a pre-determined target linewidth intended for use when employing the series of patterned mask layers 14a, 14b and 14c as a series of etch mask layers. Typically, the target linewidth is from about 0.06 to about 0.14 microns and the first linewidth is from about 0.10 to about 0.18.

FIG. 3 shows the results of measuring the first linewidth of the series of patterned mask layers 14a, 14b and 14c while employing a first linewidth measurement probe 16. The first linewidth measurement probe 16 may employ a measurement probe selected from the group including but not limited to electron microscopy probes and optical probes (such as optical microscopy, optical scattering, optical refractometry and optical reflectometry probes) . Preferably, the first linewidth measurement probe 16 is in-situ within a reactor chamber within which is further processed the microelectronic product of FIG. 3. Within FIG. 3, the first linewidth of the series of patterned mask layers 14a, 14b and 14c is measured with the first linewidth measurement probe 16 and the first linewidth is compared to the pre-determined target linewidth such as to determine a first deviation therefrom.

FIG. 4 shows the results of trimming the series of patterned mask layers 14a, 14b and 14c to form a series of once trimmed patterned mask layers 14a′, 14b′ and 14c′ while employing a first trimming environment 18 in conjunction with the first deviation. The first deviation controls the first trimming environment 18 through use of a feed forward control system.

Within the invention, the first trimming environment 18 is an etching environment intended to trim the series of once trimmed patterned mask layers 14a′, 14b′ and 14c′ such as to provide a second linewidth thereof between the first linewidth and the target linewidth. The first trimming environment 18 may employ wet chemical etchants or dry plasma etchants as are appropriate for the material from which is formed the patterned mask layers 14a, 14b and 14c.

FIG. 5 shows the results of measuring the series of once trimmed patterned mask layers 14a′, 14b′ and 14c′ while employing a second linewidth measurement probe 16′, to determine the second linewidth thereof.

When the target linewidth is from about 0.06 to about 0.14 microns and the first linewidth is from about 0.10 to about 0.18 microns, the second linewidth is from about 0.08 to about 0.16 microns. The second linewidth measurement probe 16′ may be otherwise analogous equivalent or identical to the first linewidth measurement probe 16 as illustrated in FIG. 3. Incident to measurement of the second linewidth, a second deviation of the second linewidth from the target linewidth is also determined.

FIG. 6 shows the results of further trimming the series of once trimmed patterned mask layers 14a′, 14b′ and 14c′ to form a series of twice trimmed patterned mask layers 14a″, 14b″ and 14c″ while employing a second trimming environment 18′. The further trimming of the series of once trimmed patterned mask layers 14a′, 14b′ and 14c′ to form the series of twice trimmed patterned mask layers 14a″, 14b″ and 14c″ is undertaken within the second trimming environment 18′ with consideration of the second deviation of the second linewidth from the target linewidth. The second deviation of the second linewidth controls the second trimming environment 18′ through use of the feed forward control system. The feed forward control system is at least in part preferably in-situ within a reactor chamber within which trimming occurs.

The second trimming environment 18′ may employ wet chemical etchants or dry plasma etchants analogous, equivalent or identical to those employed for the first trimming environment 18 as illustrated in FIG. 4.

Within the invention, the second trimming environment 18′ may be employed to provide the series of twice trimmed patterned mask layers 14a″, 14b″ and 14c″ either: (1) having a third linewidth between the second linewidth and the target linewidth; or (2) having a third linewidth most closely approximating the target linewidth. In accord with the former option, the invention may provide for additional sequential trimmed patterned mask layer measurement and trimming such that a series of further trimmed patterned mask layers derived from the series of twice trimmed patterned mask layers 14a″, 14b″ and 14c″ eventually has a measured linewidth that approximates the target linewidth. In accord with the latter option, the second trimming within the second trimming environment 18′ is intended to be a final trimming when forming the series of twice trimmed patterned mask layers 14a″, 14b″ and 14c″ such that the second linewidth of the series of twice trimmed patterned mask layers 14a″, 14b″ and 14c″ most closely approximates the target linewidth.

FIG. 7 shows the results of measuring the third linewidth of the series of twice trimmed patterned mask layers 14a″, 14b″ and 14c″ while employing a third linewidth measurement probe 16″.

The third linewidth measurement probe 16″ may be analogous, equivalent or identical to the first linewidth measurement probe 16 as illustrated in FIG. 3 or the second linewidth measurement probe 16′ as illustrated in FIG. 5.

FIG. 8 shows the results of etching the blanket target layer 12 to form a series of patterned target layers 12a, 12b and 12c while employing the series of twice trimmed patterned mask layers 14a″, 14b″ and 14c″ as a series of etch mask layers, in conjunction with a target layer etchant 20.

The target layer etchant 20 is selected in accord with the material from which is formed the blanket target layer 12. The target layer etchant 20 will typically be a plasma etchant. Under circumstances where the blanket target layer 12 is a blanket gate electrode material layer, the series of patterned target layers 12a, 12b and 12c is a series of gate electrodes, typically employed within a series of field effect transistor devices.

FIG. 1 to FIG. 8 show a series of schematic cross-sectional diagrams illustrating a series of process steps in forming a series of patterned target layers within a microelectronic product in accord with a preferred embodiment of the invention. The series of patterned target layers is formed with precise linewidth control by employing a sequential patterned mask layer measurement and trimming method that employs a minimum of two patterned mask layer linewidth measurements (preferably in-situ) and a corresponding minimum of two patterned mask layer trimmings, such that a multiply trimmed patterned mask layer measured linewidth more closely approximates a patterned mask layer target linewidth.

The preferred embodiment of the invention is illustrative of the invention rather than limiting of the invention. Revisions and modifications may be made to methods, materials, structures and dimensions in accord with the preferred embodiment of the invention while still providing embodiments in accord with the invention, further in accord with the accompanying claims.

1. A method for forming a patterned mask layer comprising:
providing a substrate having formed thereover a blanket mask layer;
patterning the blanket mask layer to form a patterned mask layer having a first actual linewidth greater than a pre-determined target linewidth;
measuring the first actual linewidth and determining a first deviation thereof from the pre-determined target linewidth;
trimming, while employing a first trimming method in conjunction with the first deviation, the patterned mask layer to provide a once trimmed patterned mask layer having a second actual linewidth between the first actual linewidth and the pre-determined target linewidth;
measuring at least the second actual linewidth and determining at least a second deviation thereof from the pre-determined target linewidth; and
trimming, while employing at least a second trimming method in conjunction with at least the second deviation, at least the once trimmed patterned mask layer to form at least a twice trimmed patterned mask layer having at least a third actual linewidth.

2. The method of claim 1 wherein the substrate is employed within a microelectronic product selected from the group consisting of semiconductor products, ceramic substrate products and optoelectronic products.

3. The method of claim 1 wherein the blanket mask layer is formed of a photoresist mask material.

4. The method of claim 1 wherein the blanket mask layer is formed of a hard mask material.

5. The method of claim 1 wherein the first trimming method is selected from the group consisting of wet chemical trimming methods and dry plasma trimming methods.

6. The method of claim 1 wherein the second trimming method is selected from the group consisting of wet chemical trimming methods and dry plasma trimming methods.

7. The method of claim 1 wherein the first deviation controls the first trimming method and the second deviation controls the second trimming method through use of a feed forward control system.

8. A method for forming a patterned mask layer comprising:
providing a substrate having formed thereover a blanket mask layer;
patterning the blanket mask layer to form a patterned mask layer having a first actual linewidth greater than a pre-determined target linewidth;
measuring the first actual linewidth and determining a first deviation thereof from the pre-determined target linewidth;
trimming, while employing a first trimming method in conjunction with the first deviation, the patterned mask layer to provide a once trimmed patterned mask layer having a second actual linewidth between the first actual linewidth and the pre-determined target linewidth;
measuring the second actual linewidth and determining a second deviation thereof from the pre-determined target linewidth;
trimming, while employing a second trimming method in conjunction with the second deviation, the once trimmed patterned mask layer to form a twice trimmed patterned mask layer having a third actual linewidth; and
measuring the third actual linewidth.

9. The method of claim 8 wherein the substrate is employed within a microelectronic product selected from the group consisting of semiconductor products, ceramic substrate products and optoelectronic products.

10. The method of claim 8 wherein the blanket mask layer is formed of a photoresist mask material.

11. The method of claim 8 wherein the blanket mask layer is formed of a hard mask material.

12. The method of claim 8 wherein the first trimming method is selected from the group consisting of wet chemical trimming methods and dry plasma trimming methods.

13. The method of claim 8 wherein the second trimming method is selected from the group consisting of wet chemical trimming methods and dry plasma trimming methods.

14. The method of claim 8 wherein the first deviation controls the first trimming method and the second deviation controls the second trimming method through use of a feed forward control system.

15. A method for forming a patterned layer comprising:
providing a substrate having formed thereover a blanket target layer having formed thereover a blanket mask layer;
patterning the blanket mask layer to form a patterned mask layer having a first actual linewidth greater than a pre-determined target linewidth;
measuring the first actual linewidth and determining a first deviation thereof from the pre-determined target linewidth;
trimming, while employing a first trimming method in conjunction with the first deviation, the patterned mask layer to provide a once trimmed patterned mask layer having a second actual linewidth between the first actual linewidth and the pre-determined target linewidth;
measuring the second actual linewidth and determining a second deviation thereof from the pre-determined target linewidth;
trimming, while employing a second trimming method in conjunction with the second deviation, the once trimmed patterned mask layer to form a twice trimmed patterned mask layer having a third actual linewidth; and
employing the twice trimmed patterned mask layer for forming a patterned target layer from the blanket target layer.

16. The method of claim 15 wherein the blanket target layer is formed from a material selected from the group consisting of conductor materials, semiconductor materials and dielectric materials.

17. The method of claim 15 wherein the substrate is employed within a microelectronic product selected from the group consisting of semiconductor products, ceramic substrate products and optoelectronic products.

18. The method of claim 15 wherein the blanket mask layer is formed of a photoresist mask material.

19. The method of claim 15 wherein the blanket mask layer is formed of a hard mask material.

20. The method of claim 15 wherein the first trimming method is selected from the group consisting of wet chemical trimming methods and dry plasma trimming methods.

21. The method of claim 15 wherein the second trimming method is selected from the group consisting of wet chemical trimming methods and dry plasma trimming methods.

22. The method of claim 15 wherein the patterned target layer is a gate electrode.

23. The method of claim 15 wherein the first deviation controls the first trimming method and the second deviation controls the second trimming method through use of a feed forward control system.
